(19) United States
(12) Patent Application Publication
(10) Pub. No.: US 2025/0306474 A1
(43) Pub. Date: Oct. 2, 2025

(54) Semiconductor Pattern Evaluation Method, Semiconductor Manufacturing Process Management System, and Semiconductor Pattern Evaluation System

(71) Applicant: Hitachi High-Tech Corporation, Tokyo (JP)

(72) Inventors: Kenji YASUI, Tokyo (JP); Mayuka Osaki, Tokyo (JP); Hiroaki Kasai, Tokyo (JP); Maki Kimura, Tokyo (JP); Takahiro Kawasaki, Tokyo (JP)

(21) Appl. No.: 19/096,845

(22) Filed: Apr. 1, 2025

(30) Foreign Application Priority Data
Apr. 2, 2024 (JP) 2024-059476

(51) Int. Cl. G03F 7/00

(52) U.S. Cl. CPC G03F 7/70655; G03F 7/70625; G03F 7/7065; G03F 7/706837

(57) ABSTRACT

A method for evaluating a pattern formed on a surface of a semiconductor wafer includes: setting a feature space including a plurality of features that are calculatable from sensing data of the pattern; and calculating, in the feature space, a deviation as a vector between a coordinate in the feature space calculated from an evaluation object and a coordinate of a reference point or in a reference space in the feature space set in advance as a comparison object.

### CLAIM OF PRIORITY

The present application claims priority from Japanese Patent application serial no. 2024-059476, filed on Apr. 2, 2024, the content of which is hereby incorporated by reference into this application.

### BACKGROUND OF THE INVENTION

### 1. Field of the Invention

The present invention relates to a semiconductor pattern evaluation method and a semiconductor pattern evaluation system, and more particularly to a technique that is effective when applied to the evaluation of a semiconductor pattern having a three-dimensional (3D) shape.

### 2. Description of Related Art

In a quality control process at a semiconductor manufacturing site, dimension measurement of a circuit pattern such as a gate interval is essential, and measurement techniques such as a scanning electron microscope (SEM), an optical critical dimension (OCD), and an atomic force microscope (AFM) are used.

A large number of tiny transistors are formed in a semiconductor element using a microfabrication technique such as lithography and dry etching. In addition to transistors having a two-dimensional structure in the related art, transistors having a three-dimensional structure such as FinFETs are beginning to be put into practical use in recent years.

In the transistors having a three-dimensional structure, the number of shape evaluation parameters necessary for quality control of the semiconductor element manufacture increases as compared with a case of a two-dimensional structure. For example, in the case of FinFET, in addition to a line width, main shape evaluation parameters of Fin also require measurement of three-dimensional (3D) shape dimensions such as a Fin height, a side wall angle, a radius of curvature of an upper corner, side wall roughness, and trailing.

In the two-dimensional structure in the related art, since line widths are different for heights of line patterns, it is necessary to calculate the line width after defining a range of the height, and measurement of the three-dimensional (3D) shape dimensions is required.

As a background art of the present technical field, for example, there is a technique as disclosed in Patent Literature 1. Patent Literature 1 discloses “a semiconductor device manufacturing process monitoring device capable of non-destructively measuring a cross-sectional shape of a pattern to be evaluated, a process condition of the pattern to be evaluated, or device characteristics of the pattern to be evaluated”.

Patent Literature 1 discloses that “image features effective for estimating the cross-sectional shape of the pattern to be evaluated, the process condition of the pattern to be evaluated, or the device characteristics of the pattern to be evaluated are calculated from an SEM image of the pattern to be evaluated, and the image features are compared with learning data that associates a cross-sectional shape of a pattern, a process condition of the pattern, or device characteristics of the pattern which has been stored in advance in a database with the image features calculated from the SEM image, thereby calculating the cross-sectional shape of the pattern to be evaluated, the process condition of the pattern to be evaluated, or the device characteristics of the pattern to be evaluated”.

### CITATION LIST

### Patent Literature

Patent Literature 1: JP2007-129059A

### SUMMARY OF THE INVENTION

As described above, a semiconductor pattern is becoming finer and a process thereof is becoming more complex, and a three-dimensional pattern shape, including not only a pattern width but also a height, an inclination, and the like, has come to have a significant impact on device characteristics, leading to an increasing demand for control of the three-dimensional pattern shape. When cross-section measurement is performed by a cross-section observation device, it is necessary to perform FIB processing or the like to prepare a sample for cross-section observation, and thus a measurement cost is high. Therefore, it is required to quantitatively grasp a semiconductor pattern shape in a non-destructive manner.

In Patent Literature 1, the cross-sectional shape is estimated and measured by learning a relationship between the cross-sectional shape (for example, a dimension) and the plurality of image features in advance.

However, since a plurality of pieces of shape dimension information are superimposed in the image features, it is unclear what shape dimension change each feature change indicates. Therefore, in order to ensure accuracy of estimation and measurement, training data covering a wide range of cross-sectional shape variations is required in order to separate the cross-sectional shape information in the image features.

On the other hand, for the purpose of evaluating a variation in the pattern shape, it is not essential to quantitatively grasp a specific dimension, but it is sufficient to grasp the presence or absence and a direction of the variation.

Therefore, an object of the invention is to provide a semiconductor pattern evaluation method capable of accurately evaluating, in evaluation of a semiconductor pattern, a pattern shape, a processing condition causing the pattern shape, or variations in device characteristics, a defect ratio, or the like caused by the pattern shape in a relatively simple manner, a semiconductor manufacturing process management system using the same, and a semiconductor pattern evaluation system.

In order to solve the above problems, the invention is a method for evaluating a pattern formed on a surface of a semiconductor wafer, and the method includes: setting a feature space including a plurality of features that are calculatable from sensing data of the pattern; and calculating, in the feature space, a deviation as a vector between a coordinate in the feature space calculated from an evaluation object and a coordinate of a reference point or in a reference space in the feature space set in advance as a comparison object.

The invention is a semiconductor manufacturing process management system that manages a semiconductor manufacturing process, and the semiconductor pattern evaluation method is used.

The invention is a semiconductor pattern evaluation system that evaluates a pattern formed on a surface of a semiconductor wafer, and the semiconductor pattern evaluation system includes: a server configured to store and process data, in which the server sets a feature space including a plurality of features that are calculatable from sensing data of the pattern, and calculates, in the feature space, a deviation as a vector between a coordinate in the feature space calculated from an evaluation object and a coordinate of a reference point or in a reference space in the feature space set in advance as a comparison object.

According to the invention, it is possible to achieve a semiconductor pattern evaluation method capable of accurately evaluating, in evaluation of a semiconductor pattern, a pattern shape, a processing condition causing the pattern shape, or variations in device characteristics, a defect ratio, or the like caused by the pattern shape in a relatively simple manner, a semiconductor manufacturing process management system using the same, and a semiconductor pattern evaluation system.

Problems, configurations, and effects other than those described above will become apparent in the following description of embodiments.

### BRIEF DESCRIPTION OF THE DRAWINGS

FIG. 1 is a block diagram showing a schematic configuration of a semiconductor pattern evaluation system according to each embodiment of the invention;

FIG. 2 shows diagrams showing an example of a Top-view SEM image of a semiconductor pattern captured by CD-SEM, a cross-sectional shape thereof, and a signal waveform;

FIG. 3 shows diagrams showing image features according to the invention;

FIG. 4 is a flowchart showing a pattern shape evaluation method based on image features according to a first embodiment and a second embodiment of the invention;

FIG. 5 is a diagram showing an evaluation object and a comparison object according to the first embodiment of the invention;

FIG. 6 is a diagram in which a change in a pattern shape according to the first embodiment of the invention is expressed by a coordinate and vector in a feature space;

FIG. 7 is a flowchart showing a method for associating a feature change with a change in a process parameter according to the second embodiment of the invention;

FIG. 8 is a diagram showing a change in a coordinate and vector in the feature space accompanying the change in the process parameter;

FIG. 9 is a diagram showing evaluation objects according to the second embodiment and a third embodiment of the invention;

FIG. 10 is a diagram showing a distance between each of the evaluation objects and a target point in the feature space according to the second embodiment of the invention;

FIG. 11 is a diagram showing a deviation of the evaluation object from the target point according to the second embodiment of the invention;

FIG. 12 is a diagram showing a guideline for changing the process parameter for bringing the evaluation object close to a target space according to the second embodiment of the invention;

FIG. 13 is a flowchart showing a method for evaluating in-plane uniformity of pattern shapes according to the third embodiment of the invention;

FIG. 14 is a diagram showing coordinates and labeling results of patterns in a feature space according to the third embodiment of the invention;

FIG. 15 is a diagram showing a normalized distance between each of evaluation objects and a target space in the feature space according to the third embodiment of the invention;

FIG. 16 is a diagram showing a deviation of the evaluation object from the target space according to the third embodiment of the invention;

FIG. 17 is a diagram showing a guideline for changing a process parameter for bringing the evaluation object close to the target space according to the third embodiment of the invention;

FIG. 18 is a diagram showing evaluation objects according to a fourth embodiment of the invention;

FIG. 19 is a diagram showing a normalized distance between each of the evaluation objects and a target space in a feature space according to the fourth embodiment of the invention;

FIG. 20 is a diagram showing a deviation of the evaluation object from the target space according to the fourth embodiment of the invention;

FIG. 21 is a diagram showing a guideline for changing a process parameter for bringing the evaluation object close to the target space according to the fourth embodiment of the invention; and

FIG. 22 is a diagram showing a change in a feature and a process window in consecutive steps according to a sixth embodiment of the invention.

### DESCRIPTION OF EMBODIMENTS

Hereinafter, embodiments of the invention will be described with reference to the drawings. In the drawings, the same configurations are denoted by the same reference signs, and a detailed description of the repeating parts is omitted.

### First Embodiment

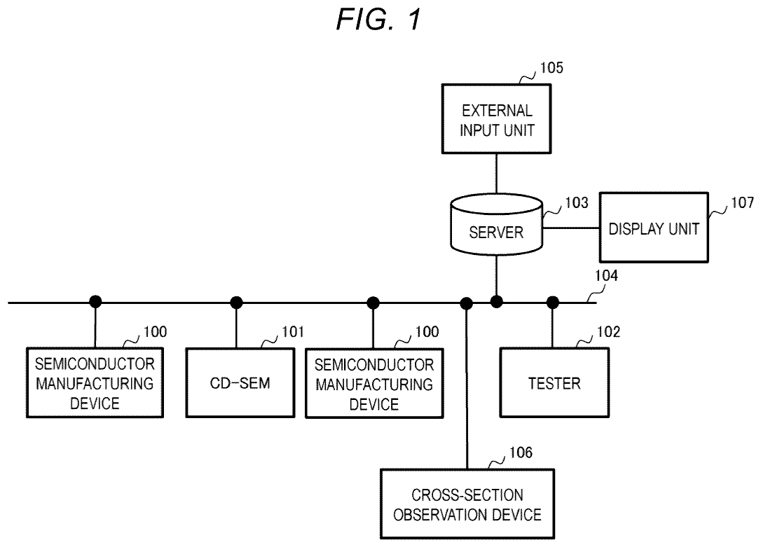

A semiconductor pattern evaluation system and a semiconductor pattern evaluation method according to a first embodiment of the invention will be described with reference to FIGS. 1 to 6.

An object of the invention is to compare and evaluate a pattern shape on a semiconductor wafer manufactured by a semiconductor manufacturing device.

In the present embodiment, line patterns are targeted, and deviations between a pattern shape at a center of the wafer as a reference and pattern shapes at different positions within a wafer surface are evaluated. In the evaluation, a plurality of image features calculated from a Top-view SEM image are used.

First, a system configuration for achieving the present embodiment will be described with reference to FIG. 1. FIG. 1 is a block diagram showing a schematic configuration of the semiconductor pattern evaluation system of the present embodiment.

As shown in FIG. 1, the present system includes, as main components, semiconductor manufacturing devices (for example, an etching device) 100, a scanning electron microscope (for example, CD-SEM) 101, an electric characteristic inspection device (tester) 102, a data storage and processing server 103, an external input unit 105, a cross-section observation device 106, and a display device (display unit) 107, which are connected to one another via a network 104. This mimics an in-line semiconductor manufacturing and inspection system.

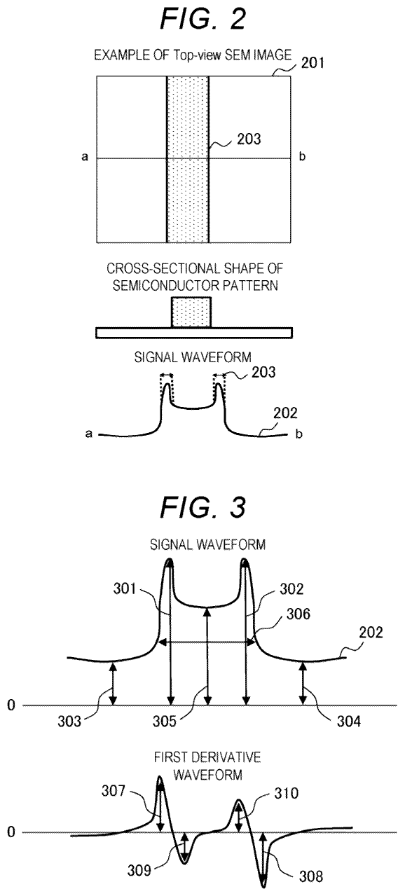

Next, the image features according to the invention will be described with reference to FIGS. 2 and 3. FIG. 2 shows diagrams illustrating an example of the Top-view SEM image obtained by imaging a semiconductor pattern with a critical dimension-scanning electron microscope (CD-SEM), a cross-sectional shape thereof, and a signal waveform. FIG. 3 shows diagrams showing the image features according to the invention.

In the SEM, image signals are acquired by irradiating a sample with an electron beam and detecting secondary electrons diffused on a surface and an inside of the sample. Therefore, the number of detected electrons changes depending on a shape of the sample, making it possible to obtain an image that is sensitive to shape information. Therefore, when the SEM image signals are compared, if the image signals are similar, it can be said that the pattern shapes of the imaged target are similar. Therefore, in order to evaluate the image signals, the image signals are quantified in a generalized manner as the plurality of image features.

FIG. 2 shows the example of the SEM image and the image signal waveform for a line pattern of a semiconductor.

On a two-dimensional SEM image 201, an image signal clipped in a direction perpendicular to a pattern (for example, from a to b in the SEM image 201 in FIG. 2) is a signal waveform 202 in a direction perpendicular to the line pattern.

In general, a signal amount of the signal waveform changes with high sensitivity to an inclination angle of a measurement target, and a signal amount on a side wall portion of the pattern is greater than a signal amount on a flat portion. Therefore, the signal amount increases at the side wall portion of the pattern, and a region called a white band 203 appears on the signal waveform 202. As described above, the signal amount of the signal waveform changes according to the shape of the cross section.

An example of the image features is shown in FIG. 3. The image features are various values quantitatively representing features of the signal waveform, such as left and right white band peaks 301, 302 of the signal waveform 202, signal amounts 303, 304 of left and right bottoms, a signal amount 305 of the top, a width 306 of the signal waveform (profile), and slopes 307 to 310 of the signal waveform calculated from a first derivative waveform. Since a local shape variation of the semiconductor pattern may also affect device performance, fluctuation or the like caused by the local shape variation of the image feature can also be used as one feature.

In general, it is considered that a feature indicating the signal amount of the signal waveform captures a change in a height direction of the pattern, a feature indicating a width of the signal waveform captures a change in a width direction such as a line width of a cross-sectional shape, and a feature indicating a slope of the signal waveform captures a change in rounding of a corner or trailing of the pattern, an inclination angle of a side wall, or the like.

However, as semiconductor patterns become finer, a diffusion range of irradiated electrons comes to include various shape dimension information such as a line width, rounding of a corner, trailing, a side wall inclination angle, and a height of a pattern. This makes it difficult to separate the various shape dimension information and design image features that can capture a change in each shape dimension independently.

Therefore, in the invention, N image features (Formula (1)) are calculated from one SEM image, and a pattern shape in the SEM image is expressed as a coordinate (vector) (Formula (2)) in a feature space having each image feature as an axis. That is, one feature set and the coordinate (vector) on the feature space thereof have correspondence with the pattern shape in one SEM image.

$${f}_{i} ( i = 1 , 2 , 3 , … , N ) \qquad ( 1 )$$

$$\vec{f} = ( {f}_{1} , {f}_{2} , {f}_{3} , … , {f}_{N} ) \qquad ( 2 )$$

By processing in this way, even if it is not possible to separate and grasp dimension information contained in each feature, it is possible to evaluate that a close distance between coordinates in the feature space means that the image signals, that is, the pattern shapes, are similar.

In this way, by expressing the pattern shapes using a plurality of feature sets and expressing the deviation as the vectors, quantitative comparative evaluation of the pattern shapes becomes possible. Further, in the invention, even in a space created by only some of the features (for example, one feature), what is indicated by the feature set is a subject of the coordinate and vector of the invention.

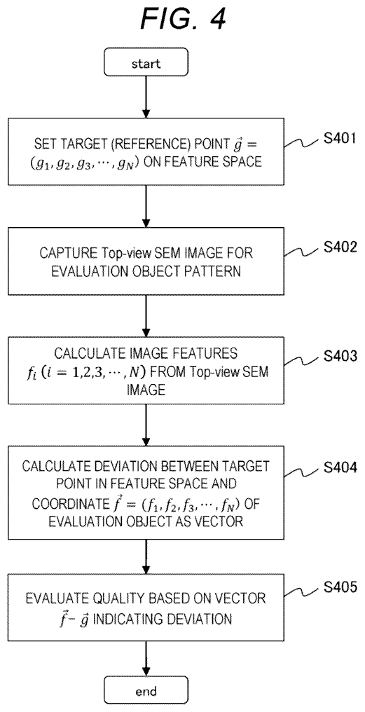

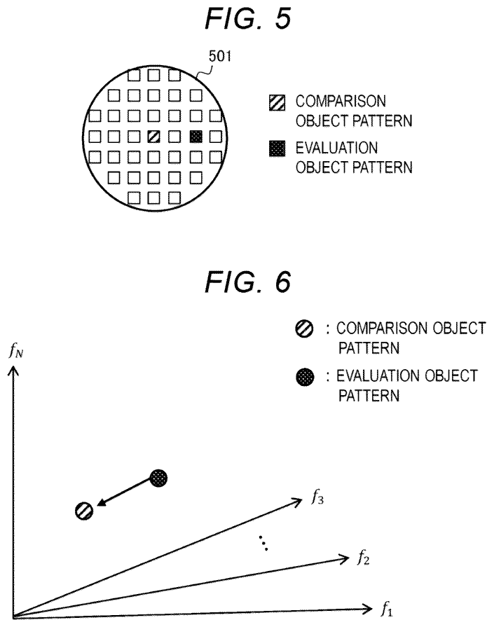

Next, the semiconductor pattern evaluation method of the present embodiment will be described with reference to FIGS. 4 to 6. FIG. 4 is a flowchart illustrating a pattern shape evaluation method based on the image features. FIG. 5 is a diagram illustrating an evaluation object and a comparison object. FIG. 6 is a diagram in which a change in the pattern shape is expressed by the coordinate and vector in the feature space.

In the present embodiment, as illustrated in FIG. 5, the comparison object is a pattern at a center of the wafer 501, and the evaluation object is a pattern at a position X at a certain distance from the center of the wafer 501.

When the data storage and processing server (hereinafter simply referred to as the “server”) 103 starts processing, first, in step S401, a target point (reference point) as the comparison object in the feature space is set. A Top-view SEM image of the pattern at the center of the wafer set as the comparison object is captured using a CD-SEM 101, and the captured image is transmitted to the server 103 via the network 104. The server 103 sets a feature set (Formula (3)) calculated from the SEM image as the target point (reference point) in the feature space, and stores the information in the server 103.

$$\vec{g} = ( {g}_{1} , {g}_{2} , ( {g}_{3} , … , {g}_{N} ) \qquad ( 3 )$$

Next, in step S402, a Top-view SEM image of the pattern at the position X at a certain distance from the center of the wafer set as the evaluation object is captured using the CD-SEM 101, and the captured image is transmitted to the server 103 via the network 104.

Next, in step S403, the server 103 calculates one or more image features (Formula (1)) from the captured Top-view SEM image of the pattern as the evaluation object.

Next, in step S404, a deviation between coordinate information of the target point (reference point) stored in the server 103 and the coordinate (Formula (2)) in the feature space of the features calculated from each chip region on the wafer 501 is calculated as a vector (Formula (4)) as illustrated in FIG. 6.

$$\vec{f} - \vec{g} \qquad ( 4 )$$

Finally, in step S405, a quality of the pattern shape is evaluated based on the calculated vector. A distance (Formula (5)) indicated by the vector becomes smaller as the pattern shape of the evaluation object becomes more similar to the pattern shape set as the target point (reference point), and becomes an index quantitatively indicating a difference from a target.

$$\vert \vec{f} - \vec{g} \vert \qquad ( 5 )$$

Application examples of the present embodiment will be described in the following embodiments.

### Second Embodiment

A semiconductor pattern evaluation system and a semiconductor pattern evaluation method according to a second embodiment of the invention will be described with reference to FIG. 4 and FIGS. 7 to 12.

In the present embodiment, in-plane uniformity of line pattern shapes on a semiconductor wafer manufactured by a semiconductor manufacturing device is evaluated using image features calculated from a Top-view SEM image, and based on an evaluation result, a process condition is set and controlled so that the in-plane uniformity meets a target value.

In general, in a process of collectively processing an entire surface of a wafer such as etching, a shape after processing may vary depending on a chip position in a wafer surface even under the same process condition. Accordingly, pattern shape changes may occur between the chip regions, and an in-plane change of the pattern shape affects device performance. Therefore, an object of the present embodiment is to set the process condition for forming patterns that achieve target performance of a device over the entire surface of the wafer, and to adjust a process to maintain the condition.

A system configuration for achieving the present embodiment is the same as that of the first embodiment (FIG. 1). The image features in the present embodiment are the same as those in the first embodiment (FIG. 3).

Processing steps of the present embodiment will be described below. The processing steps are roughly divided into four processing steps, that is, (1) creation of a model in which a change amount of a feature and a change amount of a process parameter are associated with each other, (2) evaluation of in-plane uniformity of a pattern shape using a coordinate in a feature space, (3) setting of a process condition by comparing the model with a feature vector indicating a deviation, and (4) control of a process by comparing the model with the feature vector indicating the deviation. These will be described below.

<<(1) Creation of Model in which Change Amount of Feature and Change Amount of Process Parameter are Associated with each other>>

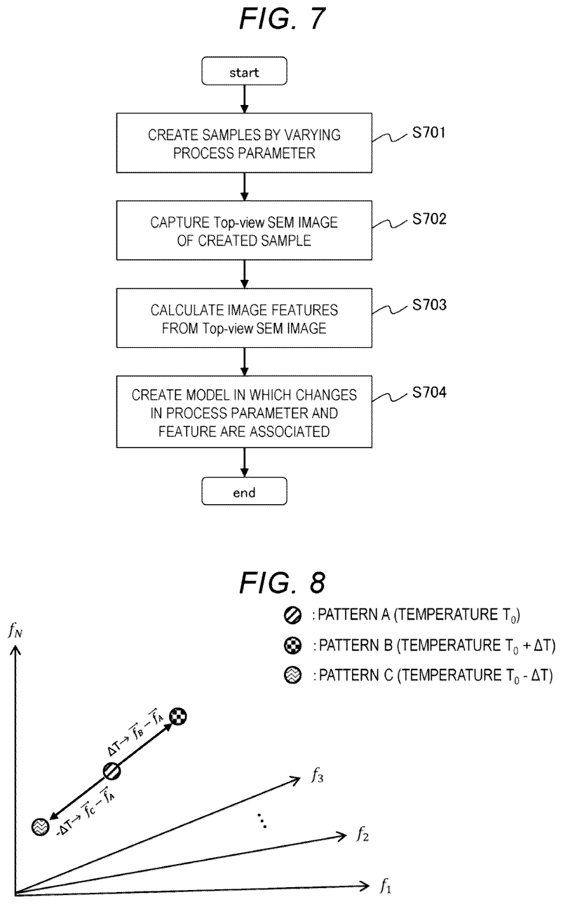

The model creation step in (1) will be described with reference to FIG. 7. FIG. 7 is a flowchart illustrating a method for associating a feature change with a change in a process parameter.

When the server 103 starts processing, first, in step S701, a plurality of samples are created by varying the process parameter (for example, a gas amount, a pressure, a temperature, and the like in the case of an etching device) that indicates the process condition in the semiconductor manufacturing device 100. Generally, when a semiconductor device manufacturing process is developed, samples are created with various process parameters, and the samples obtained there are assumed.

Next, in step S702, a Top-view SEM image of each of the samples is captured by the CD-SEM 101, a fracture surface is then captured by the cross-section observation device 106 such as a cross-section SEM or a transmission electron microscope (TEM), and the process parameters and these images are transmitted as one set to the server 103 via the network 104 and stored therein.

Next, in step S703, the server 103 calculates one or more image features (Formula (1)) from the Top-view SEM image.

Finally, in step S704, a relationship between a change in the feature accompanying the change in the process parameter is modeled based on the process condition and a feature set for the pattern shape manufactured under the condition, and the information is stored in the server 103.

As an example, FIG. 8 shows a plot of a feature calculated from a pattern generated under a certain process condition A and features calculated from patterns generated under a process condition B and a process condition C in which a temperature of an etching device is changed on the feature space.

As described above, by associating a temperature change amount with the vector representing the deviation between the coordinates on the feature space, a model that outputs a control amount and direction of the process parameter using the change amount of the feature as input is created.

Although the example in which the temperature is changed as the process parameter has been described, even when there are a plurality of process parameters, a change amount of each of the process parameters may be expressed as a vector as an element, and the model may be created by associating the vector and the process parameter.

Accordingly, it is possible to calculate which process parameter is changed in which direction to improve the in-plane uniformity when a feature variation occurs in the wafer surface, and this can be used as a basis for setting and controlling the process condition.

In the present embodiment, the plurality of samples are created by varying the process parameter, and a new model is created that associates a change in the process parameter with the change in the feature. However, if a model already exists, it is also possible to input the model via the external input unit 105. In this case, this step can be omitted.

### <<(2) Evaluation of In-plane Uniformity of Pattern Shape Using Coordinate in Feature Space>>

The in-plane uniformity evaluation step of the pattern shape in (2) will be described with reference to FIG. 4.

When the server 103 starts processing, first, in step S401, a target point (reference point) as the comparison object in the feature space is set.

In the in-plane uniformity evaluation, a certain pattern shape in the wafer is used as a comparison reference, and an object is to evaluate a deviation or a similarity with another pattern in the wafer surface. Therefore, in the present embodiment, a pattern at a center of the wafer is selected as a comparison object, and a feature set (Formula (3)) calculated from an SEM image obtained by capturing the pattern with the CD-SEM 101 is set as the target point (reference point) in the feature space.

The reason why the center of the wafer is selected as the example is that the center of the wafer generally has the best pattern shape within the surface. Further, a target pattern may be set based on a quality of a pattern manufactured under each process condition, determined from the cross-section SEM image or the TEM image stored in the server 103.

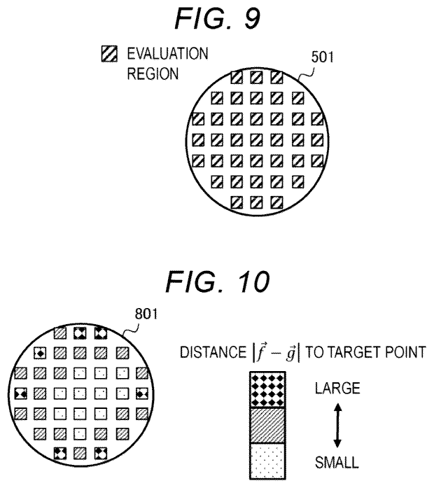

Next, in step S402, a Top-view SEM image is captured for an evaluation object using the CD-SEM 101, and the captured image is transmitted to the server 103 via the network 104. Since the purpose of the present embodiment is to evaluate the in-plane uniformity of the pattern shapes on the wafer, the pattern of each chip region on the wafer 501 is set as the evaluation object as shown in FIG. 9.

Next, in step S403, the server 103 calculates one or more image features (Formula (1)) from the Top-view SEM image.

Next, in step S404, a deviation between coordinate information of the target point (reference point) stored in the server 103 and a coordinate (Formula (2)) in the feature space of the feature calculated from each chip region is calculated as a vector (Formula (4)).

Finally, in step S405, a quality of the pattern shape is evaluated based on the vector (Formula (4)) calculated in step S404. A distance (Formula (5)) indicated by a vector becomes smaller as the pattern shape of the evaluation object becomes more similar to the pattern shape set as the target point (reference point), and becomes an index quantitatively indicating a difference from the target.

FIG. 10 shows an example of a result of calculating the distance (Formula (5)) between the coordinate of the features calculated from the pattern of each chip region and the target point.

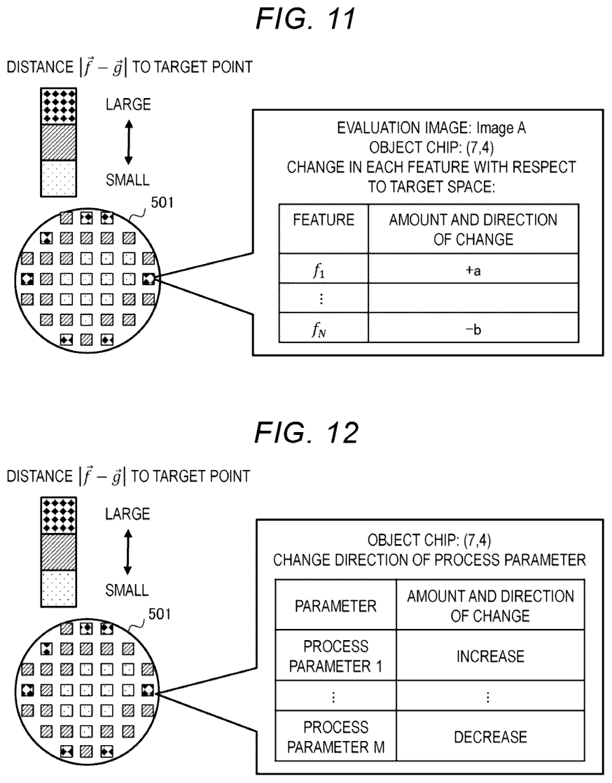

Accordingly, uniformity of cross-sectional shapes in the wafer surface with respect to a target cross-sectional shape can be evaluated. As illustrated in FIG. 11, as the deviation from the target space, an amount and a direction of the change in each feature are displayed on the display device (display unit) 107 such as a graphical user interface (GUI).

<<(3) Setting of Process Condition by Comparing Model with Feature Vector>>

Referring to FIG. 12, a process condition setting step by comparing the model with the feature vector in (3) will be described.

For each evaluation pattern in the wafer surface, the vector (Formula (4)) indicating the deviation from the target point (center of the wafer) is compared with the model in which the feature change and the change in the process parameter are associated with each other, it is calculated which process parameter is changed in which direction to bring the evaluation object closer to the target point, and a result is output as shown in FIG. 12.

Accordingly, it is possible to calculate the process condition for improving the in-plane uniformity. In the present embodiment, in order to improve the in-plane uniformity, the process parameter (for example, a temperature distribution on the wafer surface during etching) that can vary depending on a position on the wafer surface is changed.

In addition, in the model generation step of (1), with respect to the process parameter that changes according to the position in the wafer surface, the image features are also acquired from the patterns having different positions in the wafer surface, and a variation with respect to the position in the wafer surface is also acquired to create the model for each position, so that a quantitative adjustment amount of the process condition necessary for the evaluation object to approach the target space can also be calculated based on the distance to the target space.

By repeating a cycle of manufacturing the wafer using the process parameters that reflect these output results, evaluating the in-plane uniformity, and outputting guidelines for improving the process parameters, it becomes possible to set the process condition that provides good in-plane uniformity, and to develop a non-destructive process that provides good in-plane uniformity of the pattern shapes.

<<(4) Control of Process by Comparing Model with Feature Vector>>

The control of the process by comparing the model with the feature vector in (4) will be described.

In a mass manufacturing process of the semiconductor manufacturing process, the process condition determined in the process condition setting step in (3) is fixed, and the patterns are continuously manufactured under the condition. However, even if the process condition is fixed, there is a possibility that the pattern shape changes due to a process variation caused by a temporal change.

Therefore, in order to maintain the in-plane uniformity with respect to the process variation, the in-plane uniformity evaluation is evaluated as a process monitor, and similarly to (3), for each evaluation pattern in the wafer surface, the vector (Formula (4)) indicating the deviation calculated with respect to the target point (center of the wafer) is compared with the model in which the feature change and the process parameter change are associated with each other, and the change amount and the change direction of each process parameter necessary for maintaining the uniformity are calculated and input to the semiconductor manufacturing device 100, so that the process condition can be controlled.

In the present embodiment, the example in which the process condition is set and the process is controlled for the etching device has been described, but the invention can also be implemented for process parameters of other processing devices such as an exposure dose and a focus height of a lithography device.

Further, in the present embodiment, the image feature is calculated from the signal waveform, but the invention can be implemented even when the image feature is used which is a feature calculated from a two-dimensional image without calculating a signal waveform, such as a feature obtained by performing Fourier transform on an image or a luminance value calculated from the image.

In the present embodiment, the vector in the feature space is calculated as the deviation from the target space using the plurality of features, but when there is only one feature, the invention can also be implemented by calculating a signed difference from the target point as the distance and direction.

Although only one target point is set in the present embodiment, the invention can be implemented by setting a plurality of target points and calculating the distance taking into account the plurality of target points, or finding the distance to a target space formed by the plurality of target points.

In the present embodiment, the example has been described in which an in-plane shape of one wafer is set as the evaluation object, but the invention can be implemented even when a plurality of wafers and samples are evaluated.

In the present embodiment, the example in which the evaluation objects are set in different chip regions of the same wafer has been described, but the invention can be implemented even when the evaluation objects are set in regions obtained by further dividing the same chip region.

In the present embodiment, the target point is set based on the SEM image obtained by imaging the pattern created by the semiconductor manufacturing device 100, but the invention can be implemented even when the target point is set based on a SEM image created by simulation or the like.

In the present embodiment, the example in which the semiconductor pattern of the object is the line pattern has been described, but the invention can be implemented for a semiconductor pattern shape having sensitivity to SEM, such as a contact hole.

In the present embodiment, the example in which one line pattern is present in the SEM image has been described, but the invention can be implemented even when a plurality of lines, such as a periodic pattern, are included in the field of view of the SEM image.

In the present embodiment, the example in which the evaluation is performed using the SEM has been described, but the invention can also be implemented using data acquired from another sensing device having sensitivity to a cross-sectional shape, such as an optical sensing device. For example, if data which is a set of combinations of reflectances at a plurality of wavelengths for one sample is output, these sets of reflectances are essentially the same as the feature set of the invention, and the coordinate and vector is calculated based on these sets of reflectances, and thus the invention can be similarly implemented.

In the present embodiment, all of the designed image features are used, but the invention can also be implemented by selecting and reducing features to be used, for example, by selecting features that are sensitive to the process condition change based on correlation with the process parameter, by comparing the change amount in the feature with reproducibility of the feature or fluctuation caused by a local shape variation to select features having high shape sensitivity, or by selecting any feature in advance.

The server 103 may be mounted on a scanning electron microscope device, a coordinate of the reference point or in a reference space in the feature space set as the comparison object may be input to the scanning electron microscope device, the deviation from the coordinate in the feature space calculated from an image captured by the scanning electron microscope device may be calculated as the vector (Formula (4)), and the vector may be displayed on a display unit (GUI or the like) of the scanning electron microscope device.

### Third Embodiment

A semiconductor pattern evaluation system and a semiconductor pattern evaluation method according to a third embodiment of the invention will be described with reference to FIG. 7 and FIGS. 13 to 17.

In the present embodiment, in-plane uniformity of a line pattern shape on a semiconductor wafer manufactured by the semiconductor manufacturing device 100 is evaluated using an image feature calculated from a Top-view SEM image, it is determined whether a pattern shape dimension achieves an allowable range as a target on the entire wafer surface, and based on an evaluation result, a process condition is set and controlled so that the in-plane uniformity meets a target value. A purpose of the present embodiment is the same as that of the second embodiment.

A system configuration for achieving the present embodiment is the same as that of the first embodiment (FIG. 1). The image features in the present embodiment are the same as those in the first embodiment (FIG. 3).

Processing steps of the present embodiment will be described below. The processing steps are roughly divided into four processing steps, that is, (1) creation of a model in which a change amount of a feature and a change amount of a process parameter are associated with each other, (2) evaluation of in-plane uniformity of a pattern shape using a coordinate in a feature space, (3) setting of a process condition by comparing the model with a feature vector indicating a deviation, and (4) control of a process by comparing the model with the feature vector indicating the deviation. These will be described below.

<<(1) Creation of Model in which Change Amount of Feature and Change Amount of Process Parameter are Associated with each other>>

This step is the same as the processing of steps S701 to S704 of the second embodiment (FIG. 7).

### <<(2) Evaluation of In-plane Uniformity of Pattern Shape Using Coordinate in Feature Space>>

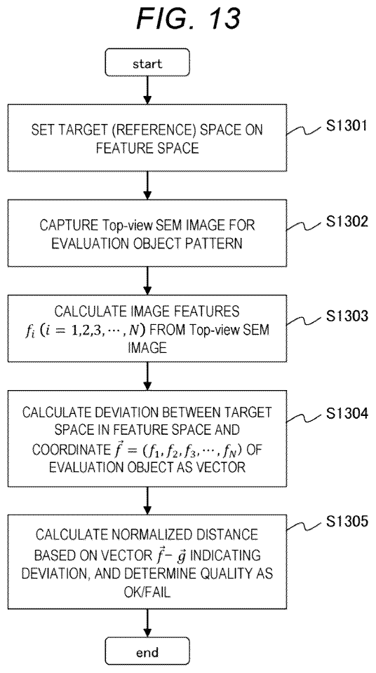

The in-plane uniformity evaluation step of the pattern shape in (2) will be described with reference to FIG. 13. FIG. 13 is a flowchart illustrating a method for evaluating the in-plane uniformity of the pattern shape.

First, a step of setting a target space in the feature space will be described. When the server 103 starts processing, first, in step S1301, a quality of a pattern manufactured under each process condition is determined as OK or FAIL based on a cross-section SEM image or a TEM image stored in the server 103, and labeled. This determination is made based on whether a specific dimension measured based on the cross-section SEM image or the TEM image is within an allowable value for achieving target device performance. A boundary in the feature space is obtained based on the labeling result, and the target space is set.

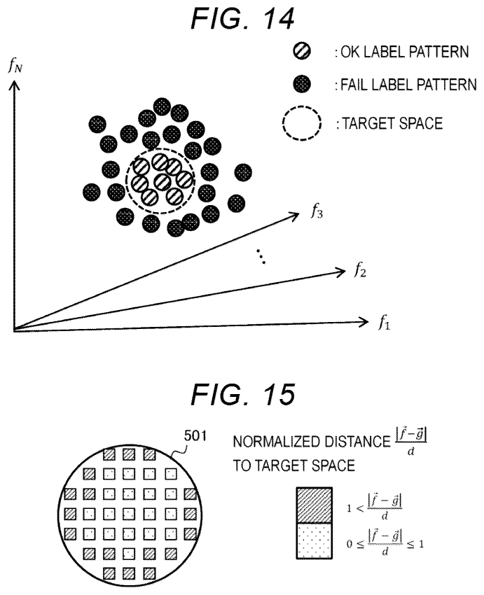

FIG. 14 illustrates an example in which image features calculated from the Top-view SEM image of each pattern to which a manufacturing process condition is assigned are plotted as coordinates in the feature space. In this graph, the labeling results of corresponding patterns are displayed as a color map.

A boundary between the OK label and the FAIL label on the feature space is calculated, a space within the boundary is set as the target space, and information thereof is stored in the server 103. Here, if it is not possible to draw a boundary that correctly distinguishes between the OK label and the FAIL label, the labels are corrected based on the cross-section SEM image or the TEM image so that the boundary can be drawn. By setting the target space in the feature space in this manner, it is possible to determine whether a cross-sectional shape satisfies a target cross-sectional shape based on the feature calculated from the Top-view SEM image.

Next, in step S1302, the Top-view SEM image is captured for an evaluation object using the CD-SEM 101, and the captured image is transmitted to the server 103 via the network 104. Since the purpose of the present embodiment is to evaluate the in-plane uniformity of the pattern shapes on the wafer, the pattern of each chip region on the wafer 501 is set as the evaluation object as shown in FIG. 9.

Next, in step S1303, the server 103 calculates image features (Formula (1)) from the Top-view SEM image.

Next, in step S1304, a deviation between the target space stored in the server 103 and a coordinate (Formula (2)) in the feature space of the feature calculated from each chip region is calculated as a vector. Here, a deviation from a barycentric coordinate (Formula (3)) of the target space is calculated as a vector (Formula (4)).

Finally, in step S1305, a quality of the pattern is evaluated based on the vector (Formula (4)) calculated in step S1304. In order to give meaning to a value of a distance (Formula (5)) from a center of gravity of the target space to the evaluation object, this value is divided by a distance d to the boundary with the target space when a straight line is extended from the center of gravity in a direction of each evaluation object, and an obtained result is defined as a normalized distance (Formula (6)).

$$\frac{\vert \vec{f} - \vec{g} \vert}{d} \qquad ( 6 )$$

When the normalized distance (Formula (6)) is equal to or smaller than 1, it can be determined that the evaluation object is in the target space, and when the normalized distance is larger than 1, so that it can be determined that the evaluation object is not in the target space, the quality of the pattern can be evaluated. Further, this normalized distance (Formula (6)) becomes smaller as the cross-sectional shape of the evaluation object becomes more similar to the target cross-sectional shape, and serves as an index that quantitatively indicates a difference between the cross-sectional shape and the target.

Here, FIG. 15 illustrates an example of a result of calculating the normalized distance (Formula (6)) between the coordinate of the feature calculated from the pattern of each chip region and the center of gravity of the target space.

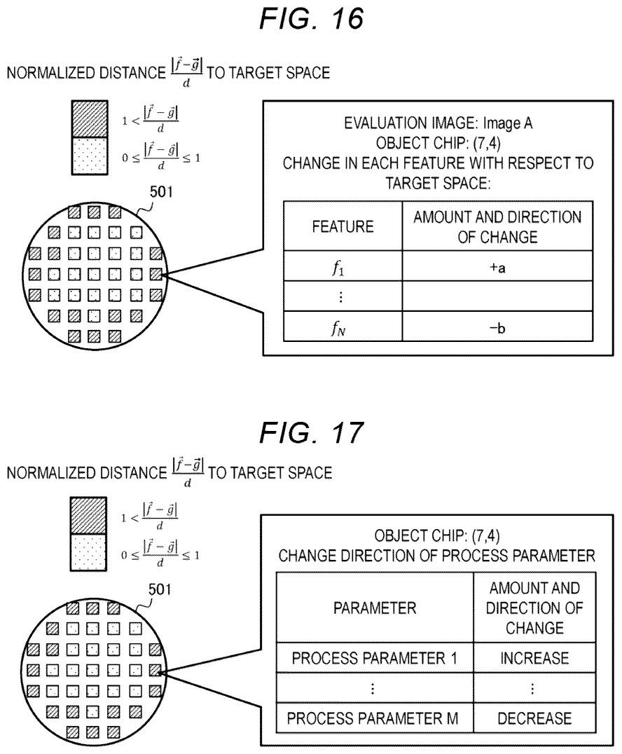

Accordingly, the uniformity of the cross-sectional shape within the wafer surface with respect to the target cross-sectional shape is indicated, and a fail pattern in which a dimension of a cross-sectional shape does not reach the target. Further, as illustrated in FIG. 16, as the deviation from the target space, an amount and a direction of the change in each feature are displayed on the display device (display unit) 107 such as a GUI.

<<(3) Setting of Process Condition by Comparing Model with Feature Vector>>

For a pattern that is outside the target space through the in-plane uniformity evaluation, that is, that is determined to has a failed quality, the vector (Formula (4)) indicating the deviation from the target space is compared with the model in which the feature change and the change in the process parameter are associated with each other, it is calculated which process parameter is changed in which direction to bring the evaluation object closer to the target space, and a result is output as shown in FIG. 17.

Accordingly, when a pattern shape that does not satisfy an allowable value within the wafer surface is obtained, the process condition for improving the shape and enhancing the in-plane uniformity can be calculated. In the present embodiment, in order to improve the in-plane uniformity, the process parameter (for example, a temperature distribution on the wafer surface during etching) that can vary depending on a position on the wafer surface is changed.

In addition, in the model generation step of (1), with respect to the process parameter that changes according to the position in the wafer surface, the image features are also acquired from the patterns having different positions in the wafer surface, and a variation with respect to the position in the wafer surface is also acquired to create the model for each position, so that a quantitative adjustment amount of the process condition necessary for the evaluation object to approach the target space can also be calculated based on the distance to the target space.

By repeating a cycle of manufacturing the wafer using the process parameters that reflect these output results, evaluating the in-plane uniformity, and outputting guidelines for improving the process parameters, it is possible to set the process condition for manufacturing the pattern that meets the target value of the in-plane uniformity, that is, that is determined as OK across the entire surface of the wafer, and to develop a non-destructive process that provides good in-plane uniformity of the pattern shapes.

<<(4) Control of Process by Comparing Model with Feature Vector>>

The control of the process by comparing the model with the feature vector in (4) will be described.

In a mass manufacturing process of the semiconductor manufacturing process, the process condition determined in the process condition setting step in (3) is fixed, and the patterns are continuously manufactured under the condition. However, even if the process condition is fixed, there is a possibility that the pattern shape changes due to a process variation caused by a temporal change.

Therefore, in order to maintain the in-plane uniformity with respect to the process variation, the patterns in the wafer surface are determined as OK/FAIL as a process monitor, and similarly to (3), for each evaluation pattern in the wafer surface which is determined as FAIL, the vector (Formula (4)) indicating the deviation calculated with respect to the target space is compared with the model in which the feature change and the process parameter change are associated with each other, and the change amount and the change direction of each process parameter necessary for maintaining the uniformity are calculated and input to the semiconductor manufacturing device 100, so that the process condition can be controlled.

In the present embodiment, the example in which the process condition is set and the process is controlled for the etching device has been described, but the invention can also be implemented for process parameters of other processing devices such as an exposure dose and a focus height of a lithography device.

Further, in the present embodiment, the image feature is calculated from the signal waveform, but the invention can be implemented even when the image feature is used which is a feature calculated from a two-dimensional image without calculating a signal waveform, such as a feature obtained by performing Fourier transform on an image.

In the present embodiment, the vector in the feature space is calculated as the deviation from the target space using the plurality of features, but when there is only one feature, the invention can also be implemented by calculating a signed difference from the target point as the distance and direction.

In the present embodiment, the example in which one target space is used has been shown, but the invention can also be implemented even when a plurality of target spaces are set, and an overlapping region of the plurality of target spaces is updated as a new target space.

In the present embodiment, the example has been described in which an in-plane shape of one wafer is set as the evaluation object, but the invention can be implemented even when a plurality of wafers and samples are evaluated.

In the present embodiment, the example in which the evaluation objects are set in different chip regions of the same wafer has been described, but the invention can be implemented even when the evaluation objects are set in regions obtained by further dividing the same chip region.

In the present embodiment, the target space is set based on the SEM image obtained by imaging the pattern created by the semiconductor manufacturing device 100, but the invention can be implemented even when the target space is set based on a SEM image created by simulation or the like.

In the present embodiment, the example in which the semiconductor pattern of the object is the line pattern has been described, but the invention can be implemented for a semiconductor pattern shape having sensitivity to SEM, such as a contact hole.

In the present embodiment, the example in which one line pattern is present in the SEM image has been described, but the invention can be implemented even when a plurality of lines, such as a periodic pattern, are included in the field of view of the SEM image.

In the present embodiment, the example in which the evaluation is performed using the SEM has been described, but the invention can also be implemented using data acquired from another sensing device having sensitivity to a cross-sectional shape, such as an optical sensing device. For example, if data which is a set of combinations of reflectances at a plurality of wavelengths for one sample is output, these sets of reflectances are essentially the same as the feature set of the invention, and the coordinate and vector is calculated based on these sets of reflectances, and thus the invention can be similarly implemented.

In the present embodiment, all of the designed image features are used, but the invention can also be implemented by selecting and reducing features to be used, for example, by selecting features that are sensitive to the process condition change based on correlation with the process parameter, by comparing the change amount in the feature with reproducibility of the feature or fluctuation caused by a local shape variation to select features having high shape sensitivity, or by selecting any feature in advance.

### Fourth Embodiment

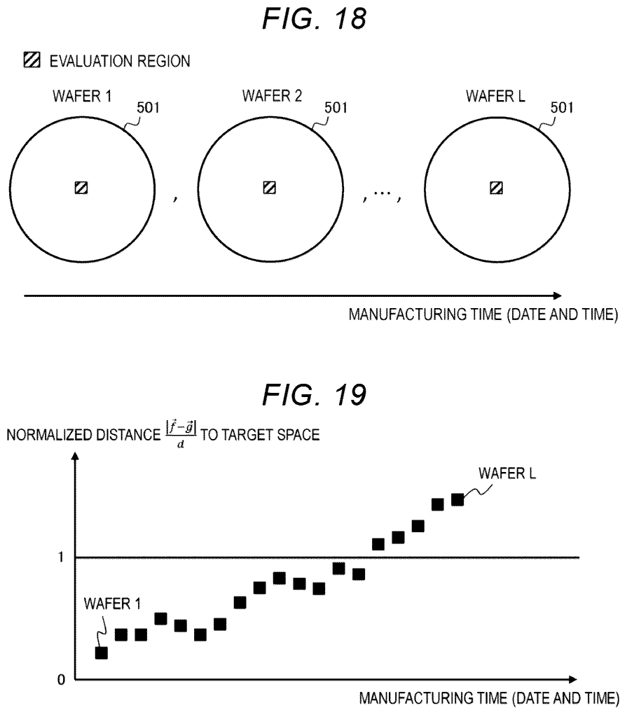

A semiconductor pattern evaluation system and a semiconductor pattern evaluation method according to a fourth embodiment of the invention will be described with reference to FIG. 7, FIG. 13, and FIGS. 18 to 21.

In the present embodiment, an example will be described in which a temporal change of a line pattern on a semiconductor wafer manufactured by the semiconductor manufacturing device 100 is evaluated using image features calculated from a Top-view SEM image, and a process condition is set and a process is controlled according to an evaluation result. An object of the present embodiment is to monitor the temporal change in a pattern shape caused by a temporal process variation because the pattern shape affects device performance, and to newly set and control the process condition when a pattern that does not satisfy target performance of a device is generated.

A system configuration for achieving the present embodiment is the same as that of the first embodiment (FIG. 1). The image features in the present embodiment are the same as those in the first embodiment (FIG. 3).

Processing steps of the present embodiment will be described below. The processing steps are roughly divided into four processing steps, that is, (1) creation of a model in which a change amount of a feature and a change amount of a process parameter are associated with each other, (2) evaluation of a process variation of the pattern shape using a coordinate in a feature space, (3) setting of the process condition by comparing the model with a feature vector indicating a deviation, and (4) control of the process by comparing the model with the feature vector indicating the deviation. These will be described below.

<<(1) Creation of Model in which Change Amount of Feature and Change Amount of Process Parameter are Associated with Each Other>>

This step is the same as the processing of steps S701 to S704 of the second embodiment (FIG. 7).

### <<(2) Evaluation of Process Variation of Pattern Shape Using Coordinate in Feature Space>>

The process variation evaluation step of the pattern shape in (2) will be described with reference to FIG. 13.

A step of setting a target space in the feature space is the same as step S1301 described in the third embodiment (FIG. 13).

Next, in step S1302, the Top-view SEM image is captured for an evaluation object using the CD-SEM 101, and the captured image is transmitted to the server 103 via the network 104. In the present embodiment, the purpose is to evaluate the temporal change of the pattern shape on the wafer caused by the process variation, and patterns in central chip regions on a plurality of wafers 501 manufactured at different times under the same process condition are set as the evaluation objects as shown in FIG. 18. The purpose of evaluating a temporal change of a cross-sectional shape is that even with the same process parameter, the pattern shape after processing may change due to the process variation over time.

Next, in step S1303, the server 103 calculates image features (Formula (1)) from the Top-view SEM image.

Next, in step S1304, a deviation between the target space stored in the server 103 and a coordinate (Formula (2)) in the feature space of the feature calculated from each chip region is calculated as a vector. Here, a deviation from a barycentric coordinate (Formula (3)) of the target space is calculated as a vector (Formula (4)).

Finally, in step S1305, a quality of the pattern is evaluated based on the vector (Formula (4)) calculated in step S1304. In order to give meaning to a value of a distance (Formula (5)) from a center of gravity of the target space to the evaluation object, this value is divided by a distance d to a boundary with the target space when a straight line is extended from the center of gravity in a direction of each evaluation object, and an obtained result is defined as a normalized distance (Formula (6)).

When the normalized distance (Formula (6)) is equal to or smaller than 1, it can be determined that the evaluation object is in the target space, and when the normalized distance is larger than 1, it can be determined that the evaluation object is not in the target space, so that the quality of the pattern can be evaluated. Further, this normalized distance (Formula (6)) becomes smaller as the cross-sectional shape of the evaluation object becomes more similar to the target cross-sectional shape, and serves as an index that quantitatively indicates a difference between the cross-sectional shape and the target.

Here, FIG. 19 illustrates an example of a result of calculating the normalized distance (Formula (6)) between the coordinate of the feature calculated from each of the evaluation patterns having different manufacturing times and the center of gravity of the target space.

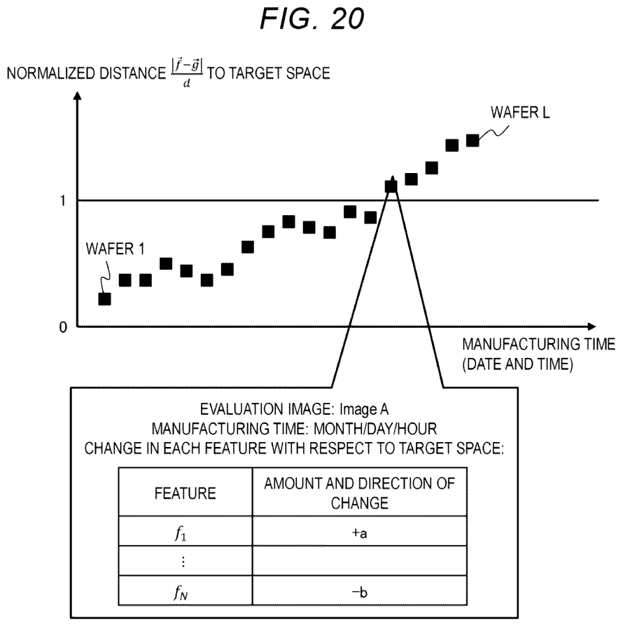

Accordingly, it is possible to show the temporal change in the pattern shape caused by the process variation relative to the target, and detect a fail pattern in which a pattern shape does not reach a target value. Further, as illustrated in FIG. 20, as the deviation from the target space, an amount and a direction of the change in each feature are displayed on the display device (display unit) 107 such as a GUI.

<<(3) Setting of Process Condition by Comparing Model with Feature Vector>>

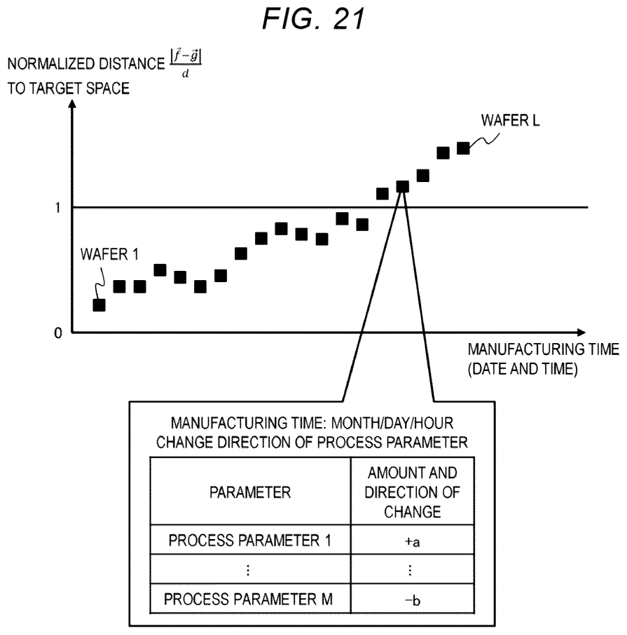

This processing assumes a case in which the process condition is newly created in response to a temporal change in the semiconductor manufacturing device 100. For a pattern that is outside the target space based on the evaluation of the temporal change in the pattern shape, that is, that is determined to has a failed quality, the vector (Formula (4)) indicating the deviation from the target space is compared with the model in which the feature change and the change in the process parameter are associated with each other, it is calculated which process parameter is changed in which direction and by how much to bring the evaluation object closer to the target space, and a result is output as shown in FIG. 21.

By repeating a cycle of manufacturing the wafer using the process parameters that reflect these output results, evaluating the pattern, and outputting guidelines for improving the process parameters, it is possible to set the process condition for manufacturing the pattern achieving the target value in response to the temporal change in the semiconductor manufacturing device 100.

<<(4) Control of Process by Comparing Model with Feature Vector>>

The control of the process by comparing the model with the feature Vector in (4) will be described.

This processing assumes a case in which the process is dynamically controlled with respect to the process variation. For a pattern that is determined to has a failed quality by evaluating the temporal change in the pattern shape as the process monitor, the vector (Formula (4)) indicating the deviation calculated with respect to the target space is compared with the model in which the feature change and the process parameter change are associated with each other, and the change amount and the change direction of each process parameter necessary for maintaining the pattern shape close to the target are calculated and input to the semiconductor manufacturing device 100, so that the process condition can be controlled.

In the present embodiment, the example in which the process condition is set and the process is controlled for the etching device has been described, but the invention can also be implemented for process parameters of other processing devices such as an exposure dose and a focus height of a lithography device.

Further, in the present embodiment, the image feature is calculated from the signal waveform, but the invention can be implemented even when the image feature is used which is a feature calculated from a two-dimensional image without calculating a signal waveform, such as a feature obtained by performing Fourier transform on an image.

In the present embodiment, the vector in the feature space is calculated as the deviation from the target space using the plurality of features, but when there is only one feature, the invention can also be implemented by calculating a signed difference from the target point as the distance and direction.

In the present embodiment, the example in which one target space is used has been shown, but the invention can also be implemented even when a plurality of target spaces are set, and an overlapping region of the plurality of target spaces is updated as a new target space.

In the present embodiment, the target space is set based on the SEM image obtained by imaging the pattern created by the semiconductor manufacturing device 100, but the invention can be implemented even when the target space is set based on a SEM image created by simulation or the like.

Further, in the present embodiment, the example in which the evaluation object is set to one chip pattern on the wafer manufactured by the same process has been described, but the invention can also be implemented by setting a plurality of chip patterns on the wafer manufactured by the same process as the evaluation objects.

In the present embodiment, the example in which the semiconductor pattern of the object is the line pattern has been described, but the invention can be implemented for a semiconductor pattern shape having sensitivity to SEM, such as a contact hole.

In the present embodiment, the example in which one line pattern is present in the SEM image has been described, but the invention can be implemented even when a plurality of lines, such as a periodic pattern, are included in the field of view of the SEM image.

In the present embodiment, the example in which the evaluation is performed using the SEM has been described, but the invention can also be implemented using data acquired from another sensing device having sensitivity to a cross-sectional shape, such as an optical sensing device. For example, if data which is a set of combinations of reflectances at a plurality of wavelengths for one sample is output, these sets of reflectances are essentially the same as the feature set of the invention, and the coordinate and vector is calculated based on these sets of reflectances, and thus the invention can be similarly implemented.

In the present embodiment, all of the designed image features are used, but the invention can also be implemented by selecting and reducing features to be used, for example, by selecting features that are sensitive to the process condition change based on correlation with the process parameter, by comparing the change amount in the feature with reproducibility of the feature or fluctuation caused by a local shape variation to select features having high shape sensitivity, or by selecting any feature specified by a user in advance.

### Fifth Embodiment

A semiconductor pattern evaluation system and a semiconductor pattern evaluation method according to a fifth embodiment of the invention will be described with reference to FIG. 13.

In the present embodiment, an example in which a target space is set based on an electric characteristic measurement result of a semiconductor device in the third embodiment or the fourth embodiment will be described.

A system configuration for achieving the present embodiment is the same as that of the first embodiment (FIG. 1). Image features in the present embodiment are the same as those in the first embodiment (FIG. 3).

In the present embodiment, in step S1301 of setting the target space in the feature space shown in FIG. 13, the semiconductor manufacturing device 100 creates a plurality of samples by variously changing a parameter serving as a process condition, captures a Top-view SEM image of the sample by the CD-SEM 101, then measures electric characteristics of the pattern by the tester 102, and transmits the process condition parameters and the image features and the electric characteristic measurement value of the pattern as one set to the server 103 via the network 104 and stores the set.

Thereafter, labeling is performed based on determination of OK/FAIL performed based on the electric characteristic measurement value, and the target space in the feature space is set based on this. Other processing is the same as those in the third embodiment and the fourth embodiment.

Accordingly, the quality of the pattern of the evaluation object can be quantitatively evaluated using the electric characteristics as a comparison reference, and the process condition can be set and controlled according to an evaluation result.

In the present embodiment, a measurement value of the electric characteristic inspection device (tester) 102 is used as the comparison reference for setting the target space, but the invention can be implemented by using an output result of other inspection and measurement devices as a comparison reference if the pattern shape of the semiconductor has an effect. Further, the invention can be implemented not only in a case in which the output result is a quantitative value, but also in a case in which the result has already been labeled as OK/FAIL and the like.

### Sixth Embodiment

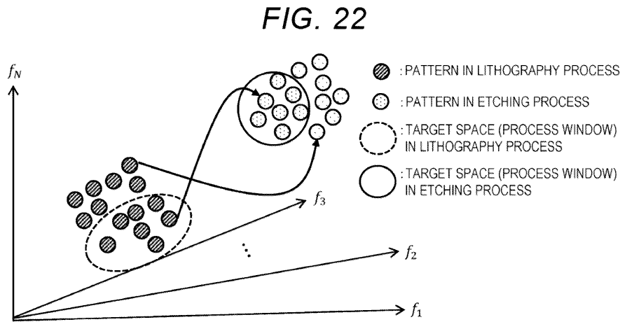

A semiconductor pattern evaluation system and a semiconductor pattern evaluation method according to a sixth embodiment of the invention will be described with reference to FIG. 22.

In the present embodiment, for two consecutive processes, a process window (target space) of a previous process (for example, a lithography process) is calculated on the assumption that a process condition of a subsequent process (for example, an etching process) and the target space in the feature space have already been determined.

An object of the present embodiment is to improve manufacturing efficiency by checking how much process margin there is in the previous process in order for the pattern shape of the subsequent process to achieve the target when the process condition of the subsequent process have been determined.

A system configuration for achieving the present embodiment is the same as that of the first embodiment (FIG. 1). Image features in the present embodiment are the same as those in the first embodiment (FIG. 3).

Processing steps of the present embodiment will be described below.

First, a plurality of samples are created by varying a process parameter (for example, an exposure dose and a focus height in the case of a lithography device) indicating the process condition in the semiconductor manufacturing device 100 (for example, the lithography device) in the previous process.

Next, a Top-view SEM image of each of the created samples is captured by the CD-SEM 101, and the process parameters and these SEM image are transmitted as one set to the server 103 via the network 104.

The samples are transmitted to the semiconductor manufacturing device 100 (for example, an etching device) in the subsequent process and processed under the predetermined process condition, a Top-view SEM image of each of the processed samples is captured using the CD-SEM 101, and the process parameters and these SEM images are transmitted as one set to the server 103 via the network 104.

The server 103 calculates an image feature set (Formula (7)) from the Top-view SEM image of the pattern in the previous lithography process, and an image feature set (Formula (8)) from the Top-view SEM image of the pattern in the subsequent etching process.

$$\vec{{f}_{p}} \qquad ( 7 )$$

$$\vec{{f}_{l}} \qquad ( 8 )$$

FIG. 22 shows a plot of these on the feature space. Arrows in this figure indicate correspondence, that is, the pattern shape of the sample manufactured in the previous lithography process is changed by the processing in the subsequent etching process.

Target space information in the subsequent process (etching process) is input to the external input unit 105, and based on whether the pattern shape (coordinate in the feature space) after the etching process falls within that target space, the corresponding pattern shape in the previous lithography process is labeled as OK/FAIL. Accordingly, the target space in the lithography process, that is, the process window can be determined.

The invention is not limited to the embodiments described above, and includes various modifications. For example, the embodiments described above have been described in detail to facilitate understanding of the invention, and the invention is not necessarily limited to those including all the configurations described above. A part of a configuration of a certain embodiment can be replaced with a configuration of another embodiment, and the configuration of another embodiment can be added to a configuration of a certain embodiment. A part of a configuration of each embodiment may be added to, deleted from, or replaced with another configuration.

What is claimed is:

1. A semiconductor pattern evaluation method for evaluating a pattern formed on a surface of a semiconductor wafer, the method comprising:
setting a feature space including a plurality of features that are calculatable from sensing data of the pattern; and
calculating, in the feature space, a deviation as a vector between a coordinate in the feature space calculated from an evaluation object and a coordinate of a reference point or in a reference space in the feature space set in advance as a comparison object.

2. The semiconductor pattern evaluation method according to claim 1, wherein
the reference point or the reference space is determined based on one of the features calculated from a pattern shape as the comparison object.

3. The semiconductor pattern evaluation method according to claim 1, wherein
the reference point or the reference space is determined based on one of the features of a pattern that achieves an index representing a process state including at least one of a device characteristic and a defect ratio as the comparison object.

4. The semiconductor pattern evaluation method according to claim 1, further comprising:
at least one of evaluating a quality of a semiconductor manufacturing process, determining a process condition for the semiconductor manufacturing process, and adjusting the process condition for the semiconductor manufacturing process based on the vector.

5. The semiconductor pattern evaluation method according to claim 1, wherein
the sensing data is an SEM image.

6. The semiconductor pattern evaluation method according to claim 5, further comprising:
determining a semiconductor manufacturing process based on a feature vector calculated by associating the features calculated from the SEM image with a parameter of the semiconductor manufacturing process.

7. The semiconductor pattern evaluation method according to claim 1, wherein
the features are values that quantitatively express features capturing a change in a three-dimensional cross-sectional shape of the pattern, the values including at least one of a value that quantitatively expresses a feature of a waveform of a line profile of the pattern, a feature that indicates a local fluctuation of the pattern, a luminance value calculated from a two-dimensional SEM image, or a value calculated by performing Fourier transform.

8. The semiconductor pattern evaluation method according to claim 1, wherein
the coordinate of the reference point or in the reference space in the feature space set as the comparison object is input to a scanning electron microscope device, the deviation from the coordinate in the feature space calculated from an image captured by the scanning electron microscope device is calculated as the vector, and the vector is displayed on a display unit of the scanning electron microscope device.

9. The semiconductor pattern evaluation method according to claim 5, further comprising:
associating the features calculated from the SEM image with a parameter of a semiconductor manufacturing process;
selecting a specific feature from the plurality of features based on a correlation with the parameter; and
determining the semiconductor manufacturing process based on a feature vector calculated using the selected feature.

10. A semiconductor manufacturing process management system that manages a semiconductor manufacturing process, wherein
the semiconductor pattern evaluation method according to claim 1 is used.

11. A semiconductor pattern evaluation system that evaluates a pattern formed on a surface of a semiconductor wafer, the system comprising:
a server configured to store and process data, wherein
the server
sets a feature space including a plurality of features that are calculatable from sensing data of the pattern, and
calculates, in the feature space, a deviation as a vector between a coordinate in the feature space calculated from an evaluation object and a coordinate of a reference point or in a reference space in the feature space set in advance as a comparison object.
